(19) United States
(12) Patent Application Publication
(10) Pub. No.: US 2016/0181457 A1
(43) Pub. Date: Jun. 23, 2016

(54) N-TYPE/P-TYPE MONOLITHIC SILICON WAFER

(71) Applicant: COMMISSARIA À L'ENERGIE ATOMIQUE ET AUX ENERGIES ALTERNATIVES, Paris (FR)

(72) Inventors: Sébastien Dubois, Scionzier (FR); Nicolas Enjalbert, Burlats (FR); Jean-Paul Garandet, Saint-Cloud (FR); Benoît Martel, Gilly Sur Isere (FR); Jordi Veirman, Genevriers (FR)

(73) Assignee: COMMISSARIA À L'ENERGIE ATOMIQUE ET AUX ENERGIES ALTERNATIVES, Paris (FR)

(21) Appl. No.: 14/978,726

(22) Filed: Dec. 22, 2015

(30) Foreign Application Priority Data
Dec. 22, 2014 (FR) 14 63124

(51) Int. Cl. H01L 31/0747; H01L 31/20

(52) U.S. Cl. CPC H01L 31/0747; H01L 31/208; H01L 31/202

(57) ABSTRACT

A process for fabricating a wafer of thickness, including at least (i) providing a monolithic substrate made of p-doped silicon; (ii) forming crystal defects in predefined portions of at least one of the sides of the substrate; (iii) subjecting the subject to a thermal anneal; (iv) bringing all or some of one of the sides of the substrate into contact with hydrogen; (v) if necessary, promoting the diffusion of the hydrogen; and (vi) subjecting the substrate to a heat treatment.

The present invention relates to a new n-type/p-type monolithic silicon wafer, and to a process for its preparation. Such a wafer is particularly advantageous in the context of the production of photovoltaic modules and cells and in particular “high-voltage” photovoltaic modules and cells.

Currently, photovoltaic (PV) modules are mainly manufactured by assembling cells made of single-crystal or polycrystalline silicon, these cells generally being produced from wafers of p-type electrical conductivity.

In PV modules of reasonable size, of about 1 m², the standard size of wafers (156×156 mm²) means that the open-circuit voltages (V_{oc}) of the PV modules are limited to a few tens of volts.

Various ways have been explored in order to try to increase the V_{oc} voltage of PV modules.

For example, recently Pozner et al, [1] have envisioned, by modeling, the series connection of cells the p-n junction planes of which are vertical, in contrast to the configuration of conventional wafers where the junction plane is horizontal. The advantage of this approach is to make it possible to envision using wafer-scale processing, of a monolithic substrate, to produce the cells. However, many technical questions remain unanswered as regards the practical production of such a structure, the cost of which moreover risks being very high.

Gatos et al. [2] propose to take advantage of the nonuniform incorporation of oxygen during the growth of a silicon crystal by directed solidification using the Czochralski process. The origin of these fluctuations in oxygen concentration is poorly understood, but this principle is used by Gatos et al, to obtain structures of alternated n/p conductivity by thermal annealing.

Specifically, it is known in the art [3] that, in silicon wafers containing oxygen, thermal anneals at temperatures of 400-500° C. allow thermal donors (TD), small agglomerates of oxygen (typically formed from the association of 3 to 20 oxygen atoms) that behave as electron donors in silicon, to be formed. Thus, when these thermal donors are generated in p-type silicon, they may lead to a compensation of the material and to a change in its conductivity. Since the liberation of electrons depends on the local concentration of oxygen, an anneal, for example at a temperature of 450° C. for 50 hours, of a wafer cut from a Czochralski ingot parallel to the solidification direction thus allows p/n structures to be obtained.

Unfortunately, the concentration fluctuations being uncontrollable, the size of the n and p zones, typically of about one hundred microns [2], cannot be controlled. It is therefore not possible to control the output voltage of such a structure and this represents a major obstacle for integration of these structures into a complete solar system.

Furthermore, the variation in size between the various subcells on the surface of a wafer introduces a complexity, from a technological point of view, that represents a major disadvantage as regards the production of the photovoltaic cells.

Another way of obtaining this type of wafer is based on local hydrogenation of the material forming the wafer, followed by an anneal (typically carried out at 450° C.) for activating thermal donors (agglomerates of oxygen atoms having an electron donor behavior). Specifically, the hydrogen accelerates the formation of the thermal donors. Thus, starting with an initially p-type wafer, after the anneal, the hydrogenated zones will be n-type, and the non-hydrogenated zones will remain p-type.

However, it is in practice difficult to introduce hydrogen right through the thickness of a silicon wafer (typically in the vicinity of 200 μm for the wafers used by the PV industry), in particular when the substrates are single-crystal substrates (absence of grain boundaries, dislocation densities lower than 10² cm⁻²).

Such substrates may be obtained by Czochralski (Cz) pulling, by the zone melting (ZM) technique, by epitaxial growth or even by seed-assisted directed solidification.

Specifically, Dubois et al. [4] have shown that during the fabrication of photovoltaic solar cells, hydrogen, initially originating from the antireflection layer of the cell, which is a hydrogenated silicon nitride (SiNx:H), migrates only over a limited distance, in the vicinity of a few tens of microns, and therefore much smaller than the thickness of the cell.

It is therefore necessary to develop processes allowing the insufficiencies detailed above of existing processes to be mitigated.

The present invention aims precisely to provide a new n-type/p-type monolithic silicon wafer allowing the aforementioned drawbacks to be mitigated, and processes for obtaining such a wafer.

More precisely, the present invention relates, according to a first of its aspects, to processes allowing a n-type/p-type wafer to be easily obtained from a p-doped silicon wafer.

The present invention in particular relates to a process for fabricating wafers as defined hereafter, which process is more particularly of interest for its ability to allow dislocations to be voluntarily and controllably generated in the volume of a single-crystal silicon wafer with the aim of improving the effects of hydrogenation of the volume.

Thus, the present invention relates to a process for fabricating a wafer (10) of thickness (e), in particular a n-type/p-type monolithic silicon wafer, and preferably such as defined hereafter, comprising at least the steps consisting in:

(i) providing a monolithic substrate made of p-doped silicon having a hole-type charge carrier concentration p₀ comprised between 10¹⁴ and 4×10¹⁶ cm⁻³ and an interstitial oxygen concentration [Oᵢ] comprised between 4×10¹⁷ and 2×10¹⁸ cm⁻³;

(ii) forming crystal defects in predefined portions of at least one of the sides of the substrate, said portions, called strain-rich regions, being spaced apart from each other by a distance d comprised between 5 μm and e/2, the distance d being measured in a vertical cross section;

(iii) subjecting the subject to a thermal anneal under conditions propitious to the propagation of dislocations from said strain-rich regions right through the thickness of the substrate;

(iv) bringing all or some of one of the sides of the substrate into contact with hydrogen under conditions adapted to diffuse the hydrogen along the dislocations propagated in step (iii);

(v) if necessary, promoting the diffusion of the hydrogen; and

(vi) subjecting the substrate to a heat treatment under conditions propitious to the activation of the oxygen-based thermal donors in the dislocation-rich zones in order to convert them into n-zones, and to obtain the expected wafer.

In the rest of the text, and unless otherwise indicated, the wafer is characterized when it is observed in its horizontal position.

Below, the expression “thermal donors”, or more simply the abbreviation “TD”, will designate oxygen-based thermal donors.

Step (iv) may be carried out between steps (iii) and (vi), but also prior to step (ii) or prior to step (iii).

Step (v) may be carried out between steps (iii) and (vi). Alternatively, it may be carried out at the same time as step (iii). Of course, step (iv) is then carried out prior to step (ii) or prior to step (iii).

Step (v) may even be carried out at the same time as step (vi).

As will become clear below, the process according to the invention allows predefined zones of the substrate to be hydrogenated effectively, and controllably in terms of location.

This result in particular relies on local formation of crystal defects on the surface of the substrate, which defects allow the size of the n- and p-zones formed in the final wafer to be controlled with precision.

Also, it is possible according to the invention, as will be seen in the rest of the text, to produce two-dimensional structures, for example with a checkerwork arrangement of alternated n- and p-zones, thereby advantageously allowing the number of subcells in series formed on the wafer to be increased.

In particular, the n-type/p-type monolithic silicon wafer (10), comprises, in a vertical cross-sectional plane, an alternation of n-doped zones and p-doped zones, characterized in that:
each of the n-doped and p-doped zones extends right through the thickness e of the wafer;
two n-doped zones are separated from each other in a vertical cross-sectional plane by a p-doped zone; and
the n-doped zones have an oxygen-based thermal donor concentration and an average dislocation density higher than those of the p-doped zones.

According to yet another of its aspects, the present invention relates to a photovoltaic device, in particular a photovoltaic cell, including a silicon wafer such as defined above.

Silicon wafers according to the invention, divided into a plurality of subcells of controlled sizes, advantageously allow PV modules having higher open-circuit voltages to be produced while preserving a reasonable standard size of about 1 m².

The expression “crystal defects” refers to known conventional single-crystal material defects, namely dislocations, voids, twins, vacancies and self-interstitials.

Other features, advantages and applications of wafers according to the invention and the process for the preparation thereof, will become more clearly apparent on reading the following detailed description of exemplary embodiments of the invention and on examining the appended drawings, in which:

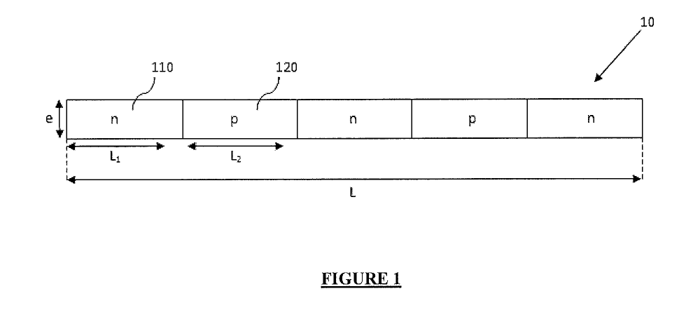

FIG. 1 schematically shows, in a vertical cross-sectional plane, the structure of a silicon wafer obtained according to the invention; and

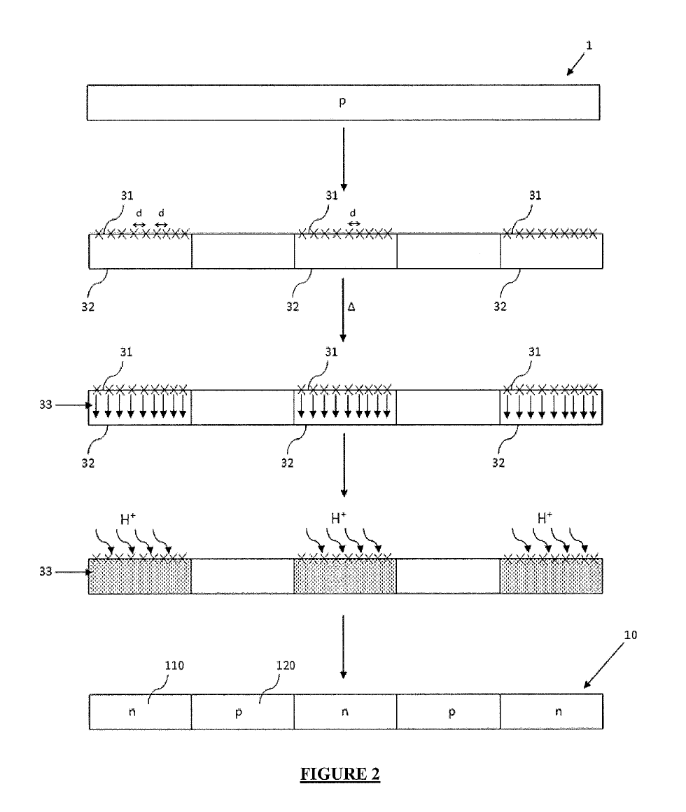

FIG. 2 schematically shows the various steps of the process for fabricating a wafer according to the invention, according to a first embodiment.

It should be noted that, for the sake of clarity, the various elements in the figures are not shown to scale, the actual dimensions of the various portions not being respected.

In the rest of the text, the expressions “comprised between . . . and . . . ”, “ranging from . . . to . . . ” and “varying from . . . to . . . ” are equivalent and understood to mean that the limits are included, unless otherwise indicated.

Unless otherwise indicated, the expression “including/comprising a” must be understood as meaning “including/comprising at least one”.

Fabrication of a N-Type/P-Type Monolithic Silicon Wafer

As mentioned above, the present invention relates to a process for fabricating a wafer 10 of thickness (e), in particular a n-type/p-type monolithic silicon wafer (10), comprising, in a vertical cross-sectional plane, an alternation of n-doped zones and p-doped zones, comprising at least the steps consisting in:

(i) providing a monolithic substrate made of p-doped silicon having a hole-type charge carrier concentration p₀ comprised between 10¹⁴ and 4×10¹⁶ cm⁻³ and an interstitial oxygen concentration [Oᵢ] comprised between 4×10¹⁷ and 2×10¹⁸ cm⁻³;

(ii) forming crystal defects in predefined portions of at least one of the sides of the substrate, said portions, called strain-rich regions, being spaced apart from each other by a distance d comprised between 5 μm and e/2, the distance d being measured in a vertical cross section;

(iii) subjecting the subject to a thermal anneal under conditions propitious to the propagation of dislocations from said strain-rich regions right through the thickness of the substrate;

(iv) bringing all or some of one of the sides of the substrate into contact with hydrogen under conditions adapted to diffuse the hydrogen along the dislocations propagated in step (iii);

(v) if necessary, promoting the diffusion of the hydrogen; and

(vi) subjecting the substrate to a heat treatment under conditions propitious to the activation of the oxygen-based thermal donors in the dislocation-rich zones in order to convert them into n-zones, and to obtain the expected wafer.

Advantageously, the substrate 1 has (111) crystal planes perpendicular to the exposed surface.

Such (111) crystal planes are advantageous in the context of the present invention; they form preferential planes of propagation of dislocations in semiconductors such as silicon.

Step (i): Monolithic Substrate Made of P-Doped Silicon

Generally, the substrate 1 made of p-doped silicon, to be processed according to the invention, comprises a hole-type charge carrier concentration p₀ comprised between 10¹⁴ and 4×10¹⁶ cm⁻³ and an interstitial oxygen concentration [Oᵢ] comprised between 4×10¹⁷ and 2×10¹⁸ cm⁻³.

According to one particular embodiment, the substrate made of p-doped silicon has an interstitial oxygen concentration [Oᵢ] ranging from 4×10¹⁷ to 1.5×10¹⁸ cm⁻³.

Advantageously, the relative variation in the interstitial oxygen concentration in the silicon substrate 1 is lower than 40%, in particular lower than 20% and preferably lower than 10%.

According to one particular embodiment, the substrate made of p-doped silicon has a hole-type charge carrier concentration (p₀) ranging from 10¹⁵ cm⁻³ to 2×10¹⁶ cm⁻³.

The hole-type charge carrier concentration may for example be deduced from a Hall effect measurement.

Preferably, the substrate is a single-crystal substrate. Such a substrate made of p-doped silicon may for example be obtained by cutting an ingot of silicon formed, using techniques known to those skilled in the art, by directed solidification of a molten bath, in particular using the gradient freeze technique, or by liquid- or gas-phase epitaxy.

The substrate may have the dimensioned indicated above for the wafer.

Step (ii): Formation of the Crystal Defects

The process according to the invention requires crystal defects to be created on the surface of at least one of the sides of the substrate.

“Predefined” portions are dedicated to forming, in the thickness of the substrate, after the process of the invention has been carried out, the n-doped zones of the final wafer.

In each of the predefined portions 31, 32, crystal defects may be created by plastically straining a substrate region located under each of the predefined portions. Such a plastic strain may be obtained by applying a force to the predefined portions.

The predefined portions integrating the crystal defects are also called “strain-rich regions”.

A strain-rich region may be defined in comparison to a strain-poor region by a strain value ΔL/L at least higher than or equal to 2 times and preferably at least higher than or equal to 3 times the strain of a strain-poor region. L is the initial length of a material and ΔL corresponds to the variation of this length when a strain is applied to the material. This strain value may be determined by n-XRD (nano X-ray diffraction).

The predefined portions are also qualified damaged portions. The dislocations will subsequently be generated from these strain-rich zones and propagated right through the thickness of the substrate.

According to one particular embodiment, the strain-rich regions are spaced apart from each other by a distance d comprised between 5 μm and e/2, in particular between 5 μm and 100 μm and preferably between 10 μm and 50 μm.

It is understood that these strain-rich regions are present on the portions dedicated to form the final n-doped zones (110) of the wafer obtained by the process according to the invention,

Thus, a final n-doped zone (110) of a wafer obtained by the process of the present invention comprises a plurality of strain-rich regions, and in particular consists of areas with strain-rich regions spaced by strain-poor regions.

According to a first variant embodiment, in step (ii), crystal defects are formed on a single side of the substrate.

According to a second variant embodiment, the crystal defects are formed on both opposite sides of the substrate. The predefined portions 31, 32 are preferably arranged symmetrically about the median longitudinal plane of the substrate, so that the n-doped zones of the wafer formed on completion of step (vi) are substantially vertical and parallel to the thickness of the substrate.

Preferably, the predefined portions 31, 32 form a network of parallel strips or a checkerwork on the surface of the substrate.

The crystal defects may be formed by scratching the surface of said predefined portions 31, 32 using a tip, in particular a micro-tip, that is preferably made of diamond or metal.

According to another variant embodiment, the crystal defects may be formed by exposing the surface of said predefined portions to laser radiation.

Such generation of strain by laser radiation is conventionally denominated shot peening, and is well known to those skilled in the art.

Preferably, the laser radiation is a laser beam the beam size of which is comprised between 1 μm and 20 μm and preferably between 2 μm and 5 μm. The laser beam preferably has one or more wavelengths longer than or equal to 100 nm and especially comprised between 400 and 5000 nm.

A plurality of laser radiation sources may be used, so as to form a comb of regularly spaced beams, in order to expose the predefined portions simultaneously.

Alternatively, it is possible to expose a plurality of predefined portions successively.

Step (iii): Thermal Anneal

The objective of step (iii) is to allow the propagation, from the strain-rich regions, of dislocations right through the thickness of the substrate.

In the rest of the text, “dislocation-rich zones” will be spoken of when designating zones subjacent to the strain-rich regions formed in step (ii), into which the dislocations are propagated. These dislocation-rich zones are more particularly zones dedicated to forming the n-doped zones on completion of step (vi) of the process of the invention.

As mentioned above, the thermal anneal may or may not be carried out conjointly with the diffusion of the hydrogen along the dislocations thus generated and into the substrate.

The thermal anneal may be carried out in an oven.

The anneal in step (iii) may for example be carried out at a temperature higher than or equal to 450° C. and lower than or equal to 1100° C. and in particular ranging from 500 to 900° C.

The duration of the thermal anneal may be shorter than or equal to 3 hours, in particular be comprised between 5 minutes and 2 hours and especially comprised between 10 minutes and 1 hour.

Such an anneal may allow dissolution (also called “annihilation”) of all of the TDs to be initiated.

In particular, the thermal anneal of step (iii) may be carried out under mechanical stresses.

Such mechanical stresses allow the effect of propagation of the dislocations from the strain-rich regions located on the surface of the substrate, right through its thickness, to be accelerated.

The mechanical stresses in step (iii) may be generated by applying to the length of the substrate a non-linear variation in temperature.

In particular, in the case where the substrate takes the form of a block or a plate, the non-linear temperature profile may consist of a parabolic type variation in temperature between the center and the opposite edges of the substrate.

In this way, uniform stresses are generated along the substrate. Specifically, the stress σ associated with a temperature variation in the substrate along a direction x is expressed by the following relationship:

$$σ = α {EW}^{2} \frac{{\partial }^{2} T}{\partial {x}^{2}}$$

in which:
α is the thermal expansion coefficient of silicon (about 3×10⁻⁶ K⁻¹);
E is the Young's modulus of silicon (1.65×10¹¹ Pa); and
W is a coefficient related to the size of the substrate that those skilled in the art will be able to determine from the size of the substrate (in meters [m]).

In order to obtain a non-linear variation in temperature between the center of the substrate and the two opposite edges, any technique known to those skilled in the art may be implemented. For example, those skilled in the art know how to implement “cold” and “hot” heat sources, applied to the center of the substrate and to the edges, respectively, so that the variation in temperature along a direction perpendicular to the opposite edges and that connects said edges is non-linear and preferably parabolic.

The variation in temperature between the edges and the center of the substrate may vary between 0.1° C. and 100° C. and preferably between 2° C. and 10° C. The stress resulting from a temperature variation may vary between 5 MPa and 2000 MPa and preferably between 10 MPa and 300 MPa.

The stresses may also be generated by bending the substrate. This embodiment allows mechanical stresses to be generated in the substrate directly.

For a 3-point bend, the maximum stress achieved by bending a plate-shaped substrate the bent side of which is of length L is related to the applied force F via the following relationship:

$${σ}_{m} = \frac{FLh}{8 I}$$

$$where$$

$$I = \frac{{Lh}^{3}}{12}$$

in which h is the thickness of the substrate.

Preferably, in the bent substrate, the maximum stress induced by the bending is comprised between 5 MPa and 2000 MPa.

For example, during the annealing step the substrate may be bent by placing its two ends on two holders made of silicon and by applying a mechanical load to the center of the substrate, for example taking the form of the weight of a body, for example one made of silicon.

This embodiment makes it possible to achieve the generation of mechanical stresses, which allow the dislocations to propagate right through the thickness of the substrate.

In order to prevent any risk of contamination, the holders holding the bent substrate and the body the weight of which exerts a force at the center of the substrate may be made of high-purity silicon, and preferably take the form of silicon beads.

In particular, the weight of the body may be adapted depending on the temperature of the thermal-annealing step (iii). Preferably, the weight of the body is comprised between 0.3 g and 30 g. Those skilled in the art will be able to adapt the weight of the body depending on the temperature and size of the substrate.

According to one preferred embodiment, the mechanical stresses are generated both by applying to the length of the wafer a non-linear variation in temperature and by bending the wafer.

Thus, the dislocations serve as diffusion “channels” for the hydrogen brought into contact with the substrate in step (iv) described below.

Step (iv): Hydrogenation

This step requires hydrogen to be brought into contact with the substrate so that the hydrogen is able to diffuse at least into the dislocation-rich zones formed in step (iii).

It is up to those skilled in the art to adjust the level of hydrogen doping in the dislocation-rich zones of the substrate so as to obtain the desired conversion of the zones in step (vi) without affecting the other regions of the substrate, which regions are dedicated to forming the p-zones of the wafer.

Generally, the doping is carried out so as to allow a uniform volumic distribution of the hydrogen in the dislocation-rich zones and right through the thickness of the substrate to be obtained.

The hydrogen may be introduced by conventional techniques, for example by a plasma treatment and especially by plasma-enhanced chemical vapor deposition (PECVD) or by microwave-induced remote hydrogen plasma (MIRHP).

Preferably, the hydrogen is introduced by an ion implantation technique or by deposition of a hydrogen-containing layer (for example by PECVD), especially of hydrogenated silicon nitride.

It is up to those skilled in the art to adjust the areal hydrogen levels introduced, especially with regard to the thickness of the substrate, so that the desired volumic doping levels are obtained on completion of the diffusion of the hydrogen right through the thickness of the substrate.

For example, step (iv) may be carried out so that the volumic doping level of the dislocation-rich zones dedicated to forming the n-doped zones is comprised between 1×10¹² cm⁻³ and 4×10¹⁴ cm⁻³.

Advantageously, the hydrogen, after it has been brought into contact with the substrate, may be diffused into the substrate by thermal annealing, especially in an oven, in particular at a temperature ranging from 450° C. to 1100° C., and for a time shorter than or equal to 3 hours.

This heat treatment may be that of step (iii), i.e, that dedicated to forming the dislocations, when the hydrogenation step is carried out prior to step (ii) or to step (iii).

According to one preferred embodiment, the hydrogen is brought into contact with only one of the sides of the substrate, and in particular the entirety of the surface of one of the sides of the substrate.

According to another embodiment, the hydrogen is brought into contact with both opposite sides of the substrate, especially after the latter has undergone step (iii).

The hydrogen may be brought into contact with all the surface of at least one of the sides of the substrate. As a variant, the hydrogen may be brought into contact only with the predefined portions of step (ii).

According to one variant embodiment, the hydrogen is brought in contact with that side of the substrate which is opposite the side on which the crystal defects were or will be formed in step (ii).

The hydrogen may be brought into contact with that side of the substrate which is opposite that on which the crystal defects were or will be formed in step (ii), in a portion of the opposite surface located facing, thicknesswise through the substrate, a predefined portion of step (ii).

According to one particularly preferred embodiment, the hydrogen is brought into contact with the entirety of that side of the substrate which is opposite the side on which the crystal defects were or will be formed in step (ii).

According to one variant, the hydrogenation step (iv) is implemented after the thermal-annealing step (iii). Preferably then, in order to promote the diffusion of the hydrogen into the dislocation-rich zones, it is preferable to implement step (v), such as described below.

According to one preferred variant, the hydrogenation step (iv) is carried out before the thermal-annealing step (iii), and after step (ii) of forming strain-rich regions. The hydrogen may especially be brought into contact with the substrate in the predefined regions using a conventional method such as described above, and remain concentrated in a surface region near the side on which it was deposited at the end of step (iv). In this variant, the thermal anneal implemented in step (iii) promotes the propagation of the dislocations right through the thickness of the substrate. The hydrogen already brought into contact with the substrate then diffuses along channels induced by the dislocations in the dislocation-rich zones, right through the thickness of the substrate.

In another variant, the hydrogenation step (iv) may be implemented before step (ii) of forming the strain-rich zones. In this variant, the hydrogen is brought into contact with the substrate before any crystal defects are formed in step (ii). Those skilled in the art will be able to define the hydrogenation zones of the substrate and the predefined portions on one side of the substrate so that, on completion of step (iii) of propagating the dislocations, the hydrogen is present in the dislocation-rich zones.

By way of illustration, it is possible to bring the hydrogen into contact with one of the sides of the substrate, for example in the form of a hydrogenated layer on all the surface of one side of the substrate, and to form the crystal defects in step (ii) on the side opposite that on which the hydrogenated layer is deposited, then to implement step (iii) so that the dislocations propagate right through the thickness of the substrate and thus, on completion of step (iii), make contact with the hydrogenated layer. The hydrogen is then able to diffuse, when step (v) such as described below is implemented, within the dislocation-rich zones, from the side on which the hydrogenated layer was deposited toward the side that is opposite thereto.

In another variant, step (iii) and step (iv) may be carried out at the same time. During the thermal anneal in step (iii), hydrogen may be deposited on one side of the substrate for example in the form of a hydrogenated layer, in such a way as to be superposed on the strain-rich regions formed in step (ii). The hydrogen may thus diffuse into the substrate as soon as it makes contact with the latter.

Step (v): Promotion of the Diffusion of the Hydrogen

As mentioned above, step (v), if it is employed, may be carried out at the same time as step (iii) in the case where step (iv) is carried out prior to step (ii) or prior to step (iii). It may also be carried out at the same time as step (vi).

In the variant in which step (iv) is carried out between steps (iii) and (vi), step (v) comprises at least one heat treatment of the substrate.

During such a heat treatment, the hydrogen concentration in the hydrogenated zones makes it possible to initiate a switch in conductivity type from p to n while leaving the weakly-hydrogenated zones p-type.

The heat treatment in step (v) may for example be a thermal anneal at a temperature comprised between 450° C. and 1000° C., and more particularly comprised between 650° C. and 800° C.

The duration of the anneal may be comprised between 40 minutes and 4 hours, and more particularly between 30 minutes and 2 hours.

Alternatively, the hydrogen may be diffused into the dislocation-rich zones by exposing said zones to ultrasound, in particular using piezoelectric transducers.

For example, it is possible to use piezoelectric transducers working between 20 kHz and 1 MHz and preferably between 50 and 500 kHz, induced acoustic strains between 5×10⁻⁶ and 2×10⁻⁵, and treatment durations between 5 and 120 minutes and preferably between 10 and 60 minutes.

Step (vi): Heat Treatment

Step (vi) allows the oxygen-based thermal donors to be activated in the dislocation-rich zones 33 in order to convert them into n-doped zones.

The heat treatment in step (vi) may for example be a thermal anneal at a temperature higher than or equal to 350° C. and lower than or equal to 550° C. and in particular ranging from 400° C. to 500° C.

The duration of the thermal anneal carried out in step (vi) may be shorter than or equal to 100 hours.

An anneal carried out at a temperature of 650° C. allows all of the TDs to be annihilated and leads to a wafer of uniform conductivity once again being obtained. This feature may advantageously be used to distinguish a wafer according to the invention from wafers that would not be obtained by a process according to the invention.

N-Type/P-Type Silicon Wafer

Reference is made, in the following description, to appended FIG. 1.

A silicon wafer 10 formed according to the invention may have a thickness e ranging from 40 μm to 600 μm and in particular from 150 μm to 250 μm.

It may have a total length L ranging from 5 cm to 30 cm and in particular from 10 cm to 20 cm.

Wafers formed according to the invention are n-type/p-type.

As indicated above, the n-doped zones 110 of the wafer formed according to the invention have an oxygen-based thermal donor concentration and an average dislocation density higher than those of the p-doped zones 120.

As will become clear from the wafer production processes described below, controlling the local TD concentration allows the alternated n and p electrical conductivity of the wafer to be achieved.

Two n-doped zones 110 are separated by one p-doped zone 120. These n-doped zones 110 and these p-doped zones 120 are advantageously arranged alternately.

It will furthermore be noted that there may be a “transition zone” between the p-doped zones and the n-doped zones, namely a zone without charge carriers, which is too thin to form an electrically insulating zone but that is neither p-doped nor n-doped.

According to one particular embodiment, the n- and p-zones may be arranged so as to form a two-dimensional pattern.

For example, in a top view of the wafer, the arrangement of the alternated n- and p-zones may form a checkerwork pattern. The side length of a square (n- and p-zones) of the checkerwork may be comprised between 1 mm and 10 cm and preferably between 5 mm and 5 cm.

According to another embodiment, the arrangement of the alternated n- and p-zones may form a strip type pattern, the width of a strip possibly being comprised between 1 mm and 10 cm and preferably comprised between 5 mm and 5 cm.

Of course, the invention is in no way limited to such arrangements. Various configurations, other than a checkerwork or strip type pattern, may be envisioned in the context of the present invention (for example rectangular patterns, polygonal patterns, etc.).

N-Doped Zones

The n-doped zones 110 of the wafer are zones rich in hydrogen.

The n-doped zones 110 possess an oxygen-based thermal donor concentration comprised between 6×10¹³ cm⁻³ and 2.5×10¹⁶ cm⁻³ and in particular comprised between 10¹⁵ cm⁻³ and 10¹⁶ cm⁻³.

The concentration of oxygen-based thermal donors may for example be evaluated by Fourier-transform infrared spectroscopy (FTIR).

On the whole, the n-doped zones 110 of the wafer may have, independently of one another, an average dislocation density higher than or equal to 10³ cm⁻², and preferably higher than or equal to 10⁵ cm⁻².

Generally, the measurement of the average dislocation density is carried out over an area of 1 mm².

The n-doped zones may have, independently of one another, a width (L₁) larger than 1 mm, preferably ranging from 1 mm to 10 cm and in particular from 5 mm to 5 cm.

The expression “independently of one another” is understood to mean that the width may differ from one doped zone to another doped zone of the same type.

P-Doped Zones

The p-doped zones 120 of the formed wafer are weakly hydrogenated zones.

The p-doped zones 120 possess an oxygen-based thermal donor concentration comprised between 10¹³ cm⁻³ and 2×10¹⁶ cm^{×3} and in particular comprised between 10¹⁴ cm⁻³ and 5×10¹⁵ cm⁻³.

According to one particular embodiment, the p-doped zones 120 of the wafer may have, independently of one another, an average dislocation density lower than or equal to 10³ cm⁻², and preferably lower than or equal to 10² cm⁻².

The p-doped zones may have, independently of one another, a width L₂ larger than 1 mm, preferably ranging from 1 mm to 10 cm and in particular from 5 mm to 5 cm.

Advantageously, the widths L ₁ , L₂ may be adjusted to meet constraints known to those skilled in the art. In particular, since n-type materials are generally less sensitive to metal impurities than p-type materials, the photogenerated currents are generally larger in the n-doped zones then in the p-doped zones. Thus, the widths L₁ , L₂ of the p-doped and n-doped zones may be adapted during the preparation of the wafer, especially with a view to balancing as well as possible these currents in the final silicon wafer.

Photovoltaic Devices

Those skilled in the art will be able to implement suitable conventional processes in order to produce a photovoltaic cell (PV) from a wafer formed according to the invention.

Preferably, on completion of the process for fabricating the wafer according to the invention, a low-temperature heterojunction technology (amorphous silicon on crystalline silicon) is used to produce the photovoltaic cell.

The PV cells obtained according to the invention may then be assembled to produce a photovoltaic module of reasonable (conventionally about 1 m²) size, and having a higher voltage relative to modules produced from conventional cells.

According to yet another of its aspects, the invention thus relates to a photovoltaic module formed from an assembly of photovoltaic cells according to the invention.

The invention will now be described by means of the following examples, of course given by way of nonlimiting illustration of the invention.

### EXAMPLE

Single-Crystal Silicon Wafer

The substrate implemented is a p-type boron-doped single-crystal silicon wafer obtained by Czochralski pulling. The initial dislocation density is about 100 cm⁻². The hole carrier content is 10¹⁵ cm⁻³, and the oxygen concentration 7×10¹⁷ cm⁻³.

The substrate is of square base of 156×156 mm² size and 200 μm in thickness.

The crystal orientation of the substrate is (100).

Formation of the Localized Zones Rich in Crystal Defects

The back side of the substrate is then locally scratched (perpendicular lines) using a diamond micro-tip. The “scratched” zones are square and 4×4 cm² in size. Tools that are already commercially available allow this type of application, with a precise control of the spatial arrangement of the scratches (the spatial resolution may be as high as micron-sized) and the mechanical engraving conditions (pressure exerted on the tip).

The parallel scratches are spaced apart by a distance of 20 μm.

In the scratched squares the dislocation density will, on completion of the process, be much higher than 10³ cm⁻².

Hydrogenation of the Surface

A standard layer of hydrogenated silicon nitride is then deposited by PECVD on the front side of the substrate, using processes known to those skilled in the art.

Propagation of the Dislocations and Diffusion of the Hydrogen

The substrate then undergoes an anneal in an inline oven for 30 minutes at 800° C. under a flow of nitrogen.

During this annealing step, the substrate is bent by placing its two ends on two holders consisting of beads of ultra-pure silicon. At the center of the wafer, 30 g of beads of ultra-pure silicon are deposited. This leads to the generation of mechanical stresses that allow the dislocations to propagate right through the thickness of the wafer, and dislocation-rich regions to be defined.

During this anneal, hydrogen initially present in the antireflection layer diffuses into the volume of the material, its migration being promoted by way of the strain-rich zones (initially “scratched” zones).

Next, the wafer undergoes an annealing step at 450° C. for 3 hours. The regions “without” dislocations will remain p-type, and the regions rich in dislocations become n-type zones.

### REFERENCES

[1] Pozner et al., Progress in Photovoltaics 20 (2012), 197;

[2] U.S. Pat. No. 4,320,247;

[3] Wijaranakula, Appl. Phys. Lett. 59 (1991), 1608;

[4] Journal of Applied Physics. 100, 024510 (2006).

1. A process for fabricating a wafer of thickness (e), comprising at least the steps:
(i) providing a monolithic substrate made of p-doped silicon having a hole-type charge carrier concentration p₀ in a range of 10¹⁴ and 4×10¹⁶ cm⁻³ and an interstitial oxygen concentration [Oᵢ] in a range of 4×10¹⁷ and 2×10¹⁸ cm⁻³;
(ii) forming crystal defects in predefined portions of at least one of the sides of the substrate, said portions, called strain-rich regions, being spaced apart from each other by a distance d in a range of 5 μm and e/2, the distance d being measured in a vertical cross section;
(iii) subjecting the subject to a thermal anneal under conditions propitious to the propagation of dislocations from said strain-rich regions right through the thickness of the substrate;
(iv) bringing all or some of one of the sides of the substrate into contact with hydrogen under conditions adapted to diffuse the hydrogen along the dislocations propagated in step (iii);
(v) if necessary, promoting the diffusion of the hydrogen; and
(vi) subjecting the substrate to a heat treatment under conditions propitious to the activation of the oxygen-based thermal donors in the dislocation-rich zones in order to convert them into n-zones, and to obtain the expected wafer.

2. The process according to claim 1, wherein step (iv) is carried out prior to step (ii), prior to step (iii), or between steps (iii) and (vi).

3. The process according to claim 1, wherein step (v) is carried out at the same time as step (iii), at the same time as step (vi), or between steps (iii) and (vi).

4. The process according to claim 1, wherein said strain-rich regions are spaced apart by a distance d in a range of 5 μm and 100 μm.

5. The process according to claim 1, wherein said strain-rich regions are spaced apart by a distance d in a range of 10 μm and 100 μm.

6. The process according to claim 1, the crystal defects being formed in step (ii) by scratching the surface of said predefined portions using a tip.

7. The process according to claim 1, the crystal defects being formed in step (ii) by scratching the surface of said predefined portions using a micro-tip made of diamond or metal.

8. The process according to claim 1, the crystal defects being formed in step (ii) by exposing the surface of said predefined portions to laser radiation.

9. The process according to claim 1, wherein said predefined portions form a network of parallel strips or a checkerwork on the surface of the substrate.

10. The process according to claim 1, wherein the thermal anneal of step (iii) is carried out under mechanical stresses.

11. The process according to claim 1, wherein the thermal anneal in step (iii) is carried out at a temperature higher than or equal to 450° C.

12. The process according to claim 1, wherein the thermal anneal in step (iii) is carried out at a temperature ranging from 500° C. to 900° C.

13. The process according to claim 1, wherein the anneal in step (iii) is carried out for a time shorter than or equal to 3 hours.

14. The process according to claim 1, wherein the anneal in step (iii) is carried out for a time ranging from 10 minutes to 1 hour.

15. The process according to claim 1, wherein step (iv) is carried out by ion implantation of hydrogen or deposition of a hydrogen-containing layer.

16. The process according to claim 1, wherein the hydrogen is brought into contact in step (iv) with the entirety of the surface of at least one of the sides of said substrate.

17. The process according to claim 1, wherein the wafer (10) is a n-type/p-type monolithic silicon wafer, comprising, in a vertical cross-sectional plane, an alternation of n-doped zones and p-doped zones, wherein:
each of the zones extends right through the thickness (e) of the wafer;
two n-doped zones are separated from each other in a vertical cross-sectional plane by a p-doped zone; and
the n-doped zones have an oxygen-based thermal donor concentration and an average dislocation density higher than those of the p-doped zones.

18. The process according to claim 1, wherein the wafer presents n-doped zones possessing an average dislocation density higher than or equal to 10³ cm⁻².

19. The process according to claim 1, wherein the wafer presents n-doped zones possessing an oxygen-based thermal donor concentration in a range of 6×10¹³ and 2.5×10¹⁶ cm⁻³.

20. The process according to claim 1, wherein the wafers presents p-doped zones possessing an average dislocation density lower than or equal to 10³ cm⁻².

21. The process according to claim 1, wherein the wafer presents p-doped zones possessing an oxygen-based thermal donor concentration in a range of 10¹³ and 2×10¹⁶ cm⁻³.
